(19) United States
(12) Patent Application Publication
(10) Pub. No.: US 2006/0006888 A1
(43) Pub. Date: Jan. 12, 2006

(54) Electrochemically fabricated microprobes

(75) Inventors: Ezekiel J. J. Kruglick, San Diego, CA (US); Christopher A. Bang, San Diego, CA (US); Vacit Arat, La Canada Flintridge, CA (US); Adam L. Cohen, Los Angeles, CA (US); Dennis R. Smalley, Newhall, CA (US); Kieun Kim, Pasadena, CA (US); Richard T. Chen, Burbank, CA (US); Gang Zhang, Monterey Park, CA (US)

Correspondence Address: MICROFABRICA INC.;ATT: DENNIS R. SMALLEY, 7911 HASKELL AVENUE, VAN NUYS, CA, 91406, US

(73) Assignee: Microfabrica Inc.

(21) Appl. No.: 10/949,738

(22) Filed: Sep. 24, 2004

Related U.S. Application Data
(63) Continuation-in-part of application No. 10/772,943, filed on Feb. 4, 2004, now abandoned.
(60) Provisional application No. 60/445,186, filed on Feb. 4, 2003.
(60) Provisional application No. 60/506,015, filed on Sep. 24, 2003.
(60) Provisional application No. 60/533,933, filed on Dec. 31, 2003.
(60) Provisional application No. 60/536,865, filed on Jan. 15, 2004.

(51) Int. Cl. G01R 31/02

(52) U.S. Cl. 324/754

(57) ABSTRACT

Multilayer probe structures for testing semiconductor die are electrochemically fabricated via depositions of one or more materials in a plurality of overlaying and adhered layers. In some embodiments the structures may include generally helical shaped configurations, helical shape configurations with narrowing radius as the probe extends outward from a substrate, bellows-like configurations, and the like. In some embodiments arrays of multiple probes are provided.

### RELATED APPLICATIONS

This application is a continuation in part of U.S. Non-Provisional patent application Ser. No. 10/772,943 filed on Feb. 4, 2004, which in turn claims benefit of U.S. Provisional Patent Application Nos.: 60/445,186; 60/506,015; 60/533,933, and 60/536,865 filed on Feb. 4, 2003; Sep. 24, 2003; Dec. 31, 2003; and Jan. 15, 2004 respectively; furthermore the present application claims benefit of U.S. Provisional Patent Application Nos.: 60/506,015; 60/533,933; and 60/536,865 filed on Sep. 24, 2003; Dec. 31, 2003; and Jan. 15, 2004, respectively. Each of these applications is incorporated herein by reference as if set forth in full herein including any appendices attached thereto.

### FIELD OF THE INVENTION

Embodiments of the present invention relate to microprobes (e.g. for use in the wafer level testing of integrated circuits), and more particularly to microprobes produced by electrochemical fabrication methods.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen® Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. (formerly MEMGen® Corporation) of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
(1) A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, August 1998.
(2) A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
(3) A. Cohen, “3-D Micromachining by Electrochemical Fabrication”, Micromachine Devices, March 1999.
(4) G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., April 1999.
(5) F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST '99), June 1999.
(6) A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
(7) F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
(8) A. Cohen, “Electrochemical Fabrication (EFAB™)”, Chapter 19 of The MEMS Handbook, edited by Mohamed Gad-El-Hak, CRC Press, 2002.
(9) Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

Electrochemical Fabrication provides the ability to form prototypes and commercial quantities of miniature objects, parts, structures, devices, and the like at reasonable costs and in reasonable times. In fact, Electrochemical Fabrication is an enabler for the formation of many structures that were hitherto impossible to produce. Electrochemical Fabrication opens the spectrum for new designs and products in many industrial fields. Even though Electrochemical Fabrication offers this new capability and it is understood that Electrochemical Fabrication techniques can be combined with designs and structures known within various fields to produce new structures, certain uses for Electrochemical Fabrication provide designs, structures, capabilities and/or features not known or obvious in view of the state of the art.

A need exists in various fields for miniature devices having improved characteristics, reduced fabrication times, reduced fabrication costs, simplified fabrication processes, and/or more independence between geometric configuration and the selected fabrication process. A need also exists in the field of miniature device fabrication for improved fabrication methods and apparatus.

### SUMMARY OF THE INVENTION

Objects and advantages of various aspects of the invention will be apparent to those of skill in the art upon review of the teachings herein. The various aspects of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

In a first aspect of the invention, a probe device for testing semiconductor die, includes: a substrate; a multi-turn compliant helical conductive element having a proximal end attached directly or indirectly to the substrate, and having a distal end that may be used to contact a pad to be tested.

In a second aspect of the invention, a probe device for testing semiconductor die, includes: a substrate; a multi-turn compliant, conical helical conductive element adhered directly or indirectly to the substrate and extending substantially perpendicular to the substrate along a winding path of progressively narrowing radius, where a distal end of the probe is substantially located at a point along an axis of helix and may be used to contact a pad to be tested.

In a third aspect of the invention, A probe device for testing semiconductor die, including: a substrate; and a multi-turn helical conductive element adhered directly or indirectly to the substrate and extending substantially perpendicular to the substrate along a spiraling path where a plurality of successive layers define the spiraling path such that it includes a pattern of deposited structural material along a given layer that only partially overlays a pattern of deposited structural material on an immediately preceding layer.

In a fourth aspect of the invention, a plurality of probes for testing semiconductor die at least some of which were formed in separate formation processes, includes: a plurality of probes formed from a plurality of adhered layers of at least one desired material, each probe having a compliance; at least one substrate for holding a plurality of probes; wherein the maximum compliance difference between a plurality of probes is less than a summation, for each layer of the plurality of probes, of an absolute value of a maximum difference between compliance associated with portions of the probes on each consecutive pair of layers.

In a fifth aspect of the invention, a plurality of separate probes for testing semiconductor die, includes: a substrate; a plurality of multi-turn helical conductive elements, each having a proximal end attached directly or indirectly to the substrate, and having a distal end that may be used to contact a pad to be tested, and each formed from a plurality of adhered layers; wherein the spacing between portions of each probe formed on each layer is greater than a spacing between each probe element.

In a sixth aspect of the invention, a plurality of separate probes for testing semiconductor die, includes: a substrate; a plurality of multi-turn helical conductive elements, each having a proximal end attached directly or indirectly to the substrate, and having a distal end that may be used to contact a pad to be tested, and each formed from a plurality of adhered layers; wherein the probes overlap in space but do not contact one another during anticipated levels of compression during use.

In a seventh aspect of the invention a probe device for testing semiconductor die, includes: a substrate; a bellows-like, compliant, conductive element having a proximal end attached directly or indirectly to the substrate, and having a distal end that may be used to contact a pad to be tested.

Further aspects of the invention will be understood by those of skill in the art upon reviewing the teachings herein. Other aspects of the invention may involve combinations of the above noted aspects of the invention with one another or with various features of the different embodiments set forth herein. Other aspects of the invention may involve apparatus that can be used in implementing one or more of the method aspects of the invention. These further aspects of the invention may provide various other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example apparatus subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself.

FIGS. 5A-5C depict various views of the CAD design of a helical spring-type microprobe element according to an embodiment of the invention.

FIG. 5D depicts a number of helical spring-type contact elements of FIGS. 5A-5C which are to be formed together in an array.

FIG. 5E depicts an SEM image of the microstructures of FIG. 5D created using an electrochemical fabrication process.

FIG. 6 depicts a substrate containing a plurality of devices similar to those shown in FIG. 5B which have been heat treated and wherein one of the devices has been subjected to a tensional force that has stretched the structure beyond the elastic limits of the material wherein the structure behaved monolithically (i.e. adhesion at the layer boundary did not fail).

FIG. 7A depicts a perspective view of a bellows type compliant probe element with an offset contact element located above a contact pad.

FIG. 7B depicts a perspective view of an array of bellows type compliant probe elements similar to that shown in FIG. 7A with offset contact elements located above contact pads.

FIG. 8A depicts a perspective view of an another bellows-type compliant probe element,

FIG. 8B depicts a cut view as seen along lines 8(b)-8(b) of a portion of the same probe element of FIG. 8A such that the interior portions of the probe may be seen.

FIG. 8C depicts a perspective view of an array of the bellows-type probes of FIGS. 8A and 8B which are mounted on a substrate.

FIGS. 8D-8F depict additional examples of bellows-like probe elements where different numbers of collapsible structures are provided, and/or different probe tip configurations are provided.

FIGS. 8G and 8H depict perspective views of two additional probes that offer compliance in a manner similar to the bellows-like structures of FIGS. 8A-8F.

FIGS. 9A-9C depict various views of CAD designs of a helical probe element according to some embodiments of the invention where a contact element is shown as being positioned toward the central axis of the probe.

FIGS. 9D-9G depict designs of various helical probe structures having different numbers of turns, different pitches, different lengths, and/or different tip configurations wherein the stair stepping of each layer is made a part of the design as opposed to allowing a slicing or layering operation to insert quantized levels, or stair steps, into a sloping helically designed structure.

FIG. 9H depicts a helical probe, either of the sloped configuration which was quantized as a result of a layering operation or which was designed to have stair steps, which has been formed in an electrochemical fabrication process.

FIG. 9I provides a perspective view of an array of helical probes similar to that of FIG. 9H.

FIG. 10 provides a perspective view of an alternative helical probe design where the spiraling rings take on a more rectangular shape and where the stair steps which would result from a layer-by-layer build up of spiraling structure are shown.

FIGS. 11A-11E provide various views of an alternative helical probe configuration where the radius of the spiraling elements decreases with increasing distance from a substrate and where an enhanced support structure is added to the region of spiraling arm that lifts or separates from the substrate.

FIG. 12 provides a perspective view of another alternative helical probe configuration that is similar to that depicted in FIGS. 9A-9C with the exception that a fixed rod, i.e. a “keeper”, is located in the central opening of the helix which limits the horizontal, i.e. lateral, displacement that the helical can undergo when it is subjected to a compressive force.

FIG. 13A provides a perspective view of part of a basic compliant structure from which probe elements may be formed.

FIGS. 13B and 13C provide two different perspective views of a probe element created from a plurality of the basic structures of FIG. 13A.

FIGS. 13D-13F provide various views of an array of the probe structures of FIGS. 13B and 13C where the elements are set into the array at slight angles to one another to allow tighter packing of the individual probes.

FIG. 14A shows a probe design based on a series of rings separated by oblique arms according to another embodiment of the invention.

FIG. 14B provides a perspective view of two back-to-back units of the probe structure of FIG. 14A.

FIGS. 15A and 15B depict a probe array chip (probe chip) according to another embodiment of the invention.

FIGS. 15C-15G depict enlarged views and alternative views to how a probe chip may be temporarily be mounted or contacted to a space transformer.

FIGS. 16A-16B provide perspective views of double helix probes according to other embodiments of the invention.

FIG. 16C. provides a perspective view of a design of a double helix probe which depicts layer-to-layer discontinuities (i.e. stair steps) that may result from a layer-by-layer build up of the structure.

FIG. 16D. provide a perspective view of an SEM image of a double helix probe structure similar to that of FIG. 16D but with fewer complete turns and with a contact tip formed at its upper end.

FIG. 17 depicts an array of tessara-like probes each possessing compliant double S-shaped elements separated from one another by end supports and with post-like structures on the upper surface of the top element and on the lower surface of the bottom element.

FIG. 18A depicts and array of four probe elements while FIG. 18B depicts a similar array with the probe elements connected to one another near there tips

FIG. 19A depicts a perspective view of another embodiment of the invention which provides double helical probe structures with spiral elements (elements that extend ½ a full turn) form separate spiral sections that attach to spaced but centrally located elements.

FIG. 19B depicts a perspective view of another embodiment of the invention which provides double helical probe structures with spiral elements (elements that extend 1 full turn) form separate spiral sections that attach to spaced but centrally located elements.

FIG. 19C depicts a perspective view of two layer levels of a probe of FIG. 19B. alternative.

### DETAILED DESCRIPTION OF PREFERRED EMBODIMENTS OF THE INVENTION

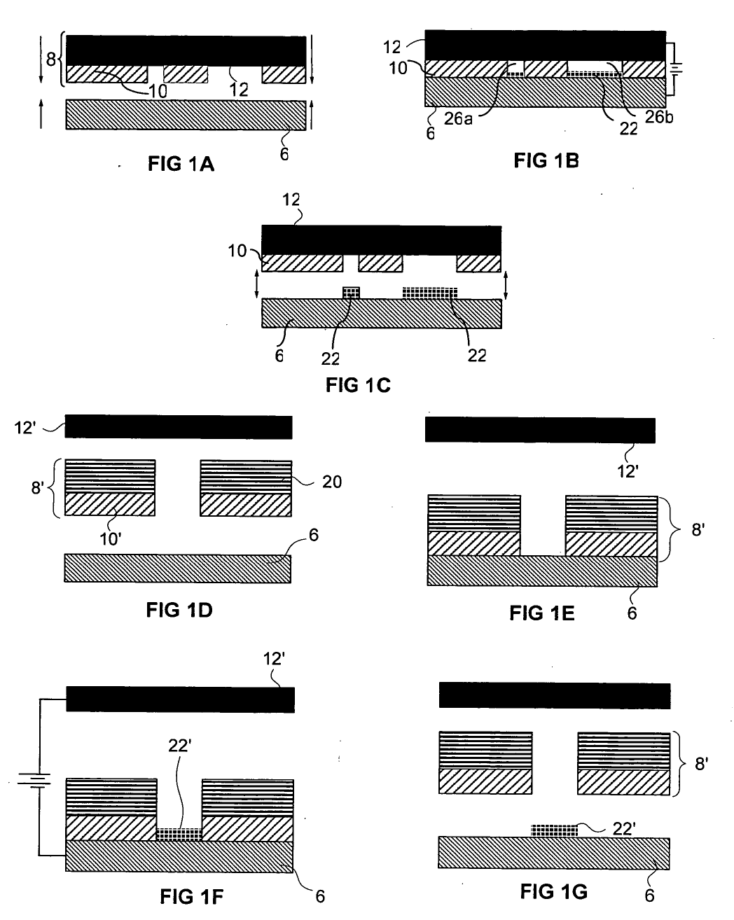

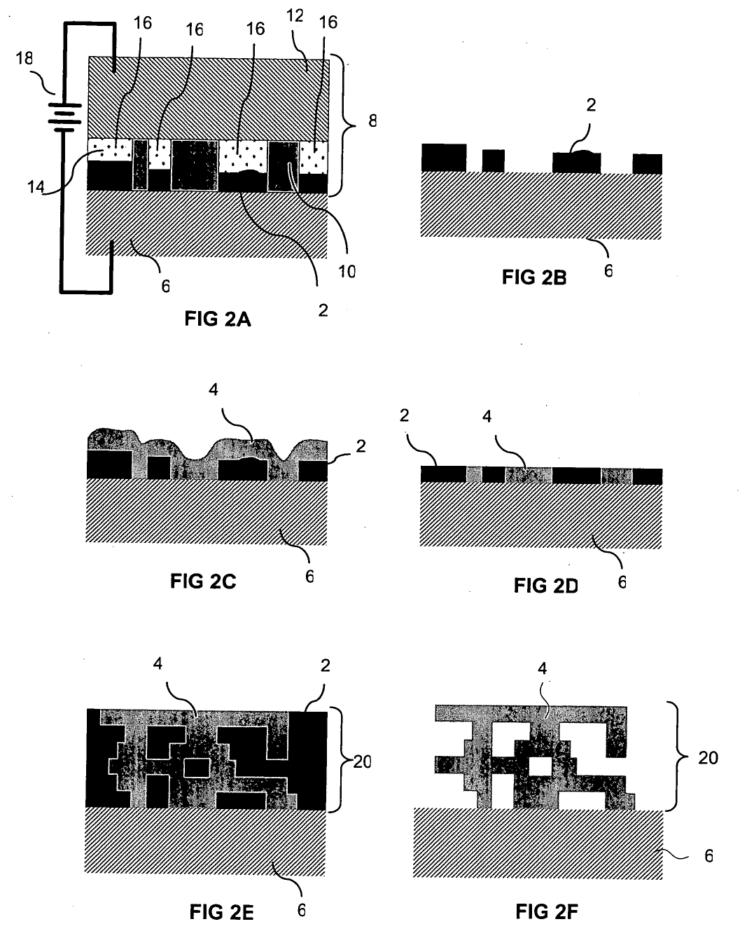

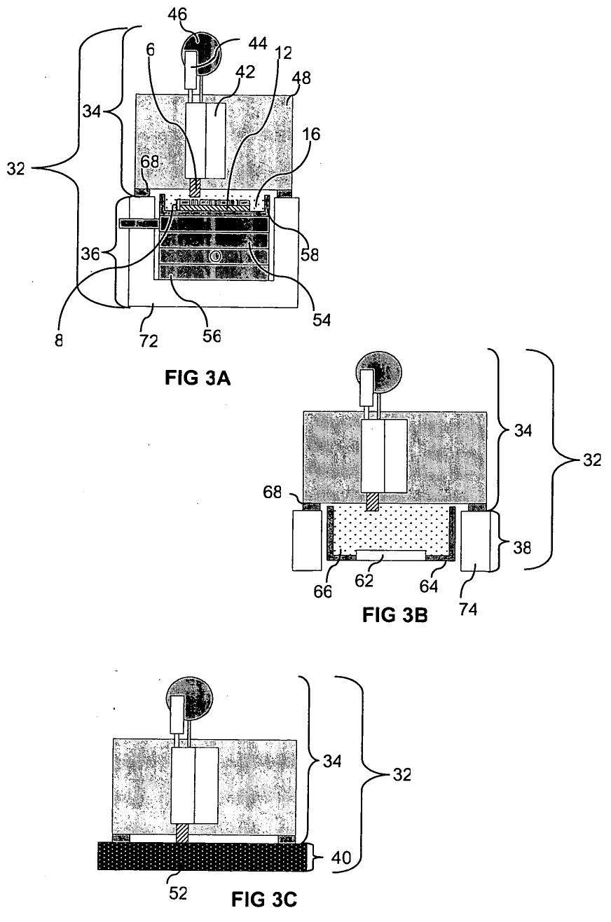

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

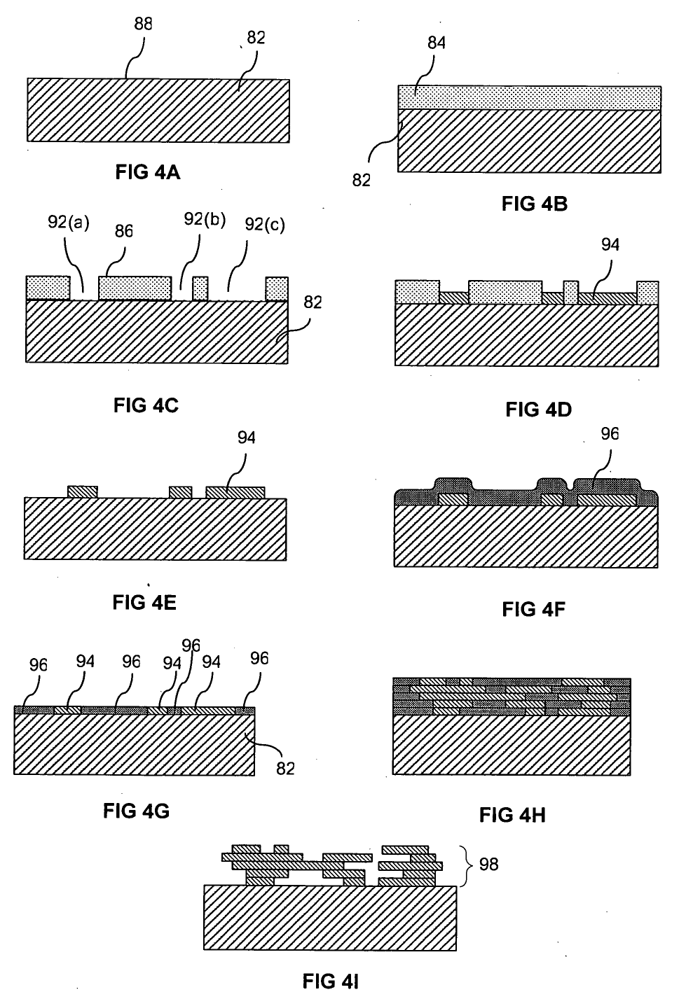

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

The various embodiments, alternatives, and techniques disclosed herein may be combined with or be implemented via electrochemical fabrication techniques. Such combinations or implementations may be used to form multi-layer structures using a single patterning technique on all layers or using different patterning techniques on different layers. For example, different types of patterning masks and masking techniques may be used or even techniques that perform direct selective depositions without the need for masking. For example, conformable contact masks may be used during the formation of some layers while non-conformable contact masks may be used in association with the formation of other layers. Proximity masks and masking operations (i.e. operations that use masks that at least partially selectively shield a substrate by their proximity to the substrate even if contact is not made) may be used, and adhered masks and masking operations (masks and operations that use masks that are adhered to a substrate onto which selective deposition or etching is to occur as opposed to only being contacted to it) may be used.

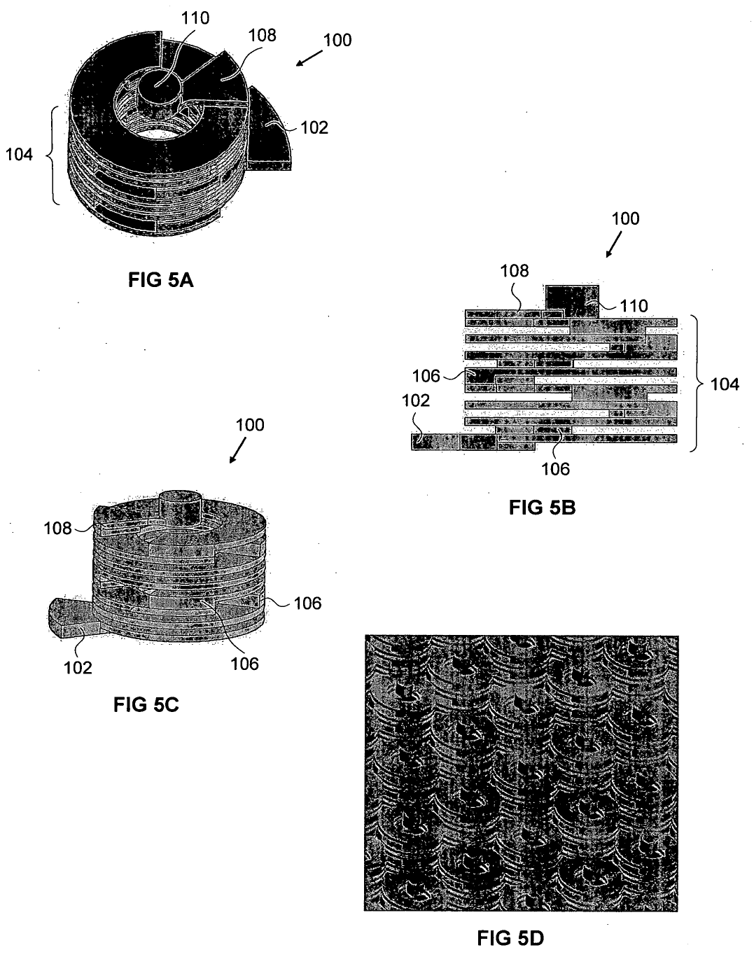

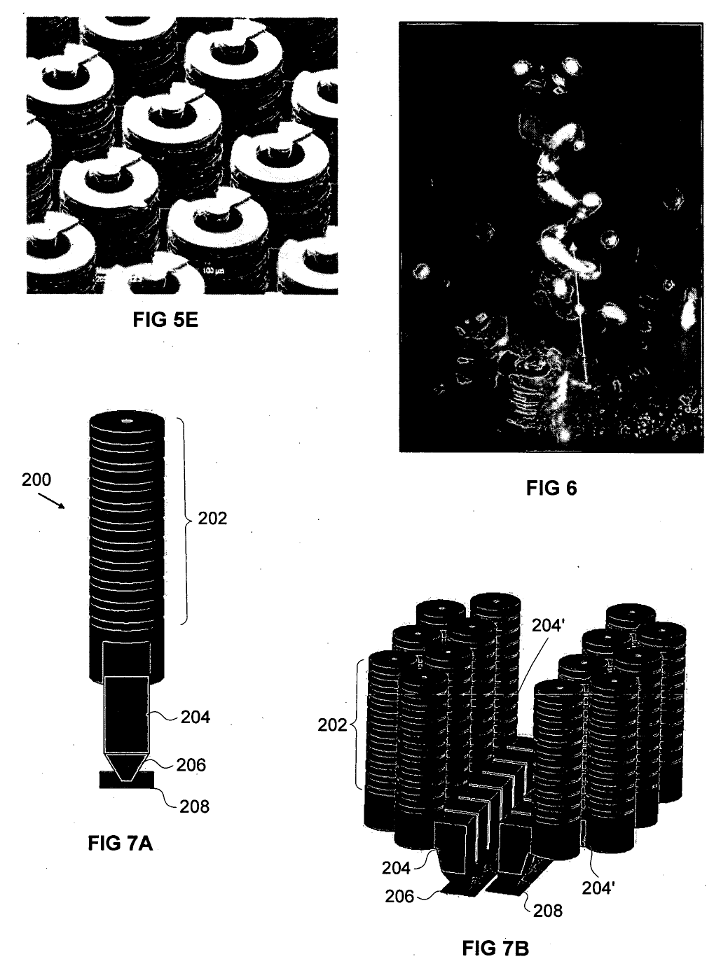

FIGS. 5A-5C depict various views of the CAD design of a helical spring-type microprobe 100 of a first embodiment of the invention. The probe comprises a base portion 102 that will be formed on or bonded to a conductive pad of a substrate (e.g. a pad of a space transformer, an interposer, an integrated circuit, semiconductor die, or other electronic component—not shown). The probe has intermediate compliant portion 104 that includes a number of partial ring-like turns that begin and end with stair stepped transitions from lower and to higher levels. In this embodiment the transitions consist of a layer of material that represents the intersection of a coil from the previous layer with the coil of a subsequent layer. In other words, the a stair step layer exists that does not extend beyond the end of the prior layer and the subsequent layer completely overlaps the transition level. The last coil connects to a contact arm 108 that directs the conductive path formed by the coil to the top center of coil on which a contact post 110 is mounted. In some embodiments, a tip of desired shape and orientation may be added to the contact post 110 while in other embodiments the contact post may act as a contact tip. In some versions of the embodiments the probe may include 8 ring or coil levels (as shown) while other embodiments may include a smaller number of coils (i.e. 1-7 levels) or a large number of levels (e.g. 9-20 levels or more). In illustrated design the thickness of each layer is 8 microns, the width of each helical element is 80 microns, the diameter of the overall helical element (excluding the base element) is 200 microns, and the overall height is 160 microns. In other embodiments, the base portion may take on different configurations and may be formed form more than one layer. In other embodiments, the rings may have different diameters, widths, and/or thickness. Each ring may be formed from a single layer (as shown) or from a plurality of layers. In some embodiments each ring element may take on different heights, widths, and diameters compared to other rings. In different embodiments, the length (or portion of a circle occupied by each ring may be different.

FIG. 5D depicts a number of helical spring-type contact elements of FIGS. 5A-5C which are to be formed together in an array. Though a regular substantially square array of probes is shown, in other embodiments, other array patterns may be created depending, for example, on the pattern of pads to which contact is to be made.

FIG. 5E depicts an SEM image of a sample array of microprobe structures fabricated using an electrochemical fabrication process.

FIG. 6 depicts a substrate containing a plurality of devices similar to those shown in FIG. 5E which have been heat treated and wherein one of the devices has been subjected to a tensional force that has stretched the structure beyond the elastic limits of the material wherein the structure behaved plastically and monolithically (i.e. adhesion at the layer boundary did not fail prior to a failure in interlayer adhesion).

FIG. 7A depicts a perspective view of a bellows-type compliant probe element 200 with a compliant bellows-like section 202 with an offset contact arm 204 located on its lower surface. The contact arm 204 in turn supports a contact element 206 which may is used in contacting a contact pad when the two are brought into relative contact. FIG. 7B depicts a perspective view of an array of bellows type compliant probe element similar to that shown in FIG. 7A with neighboring probes being spaced in an offset manner from one another to allow closer spacing of contact tips where every other probe has a cantilever arm (204 and 204′) of different length.

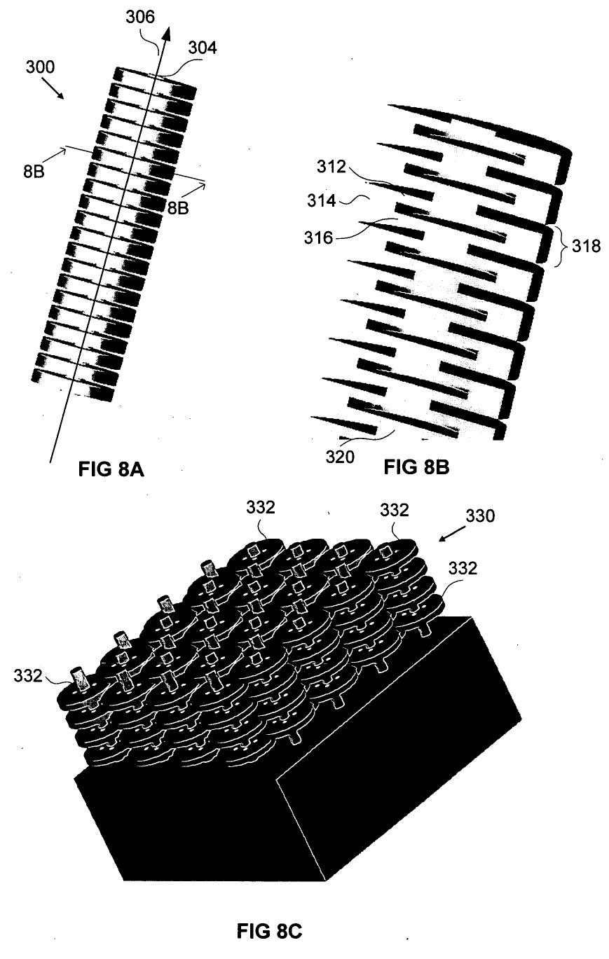

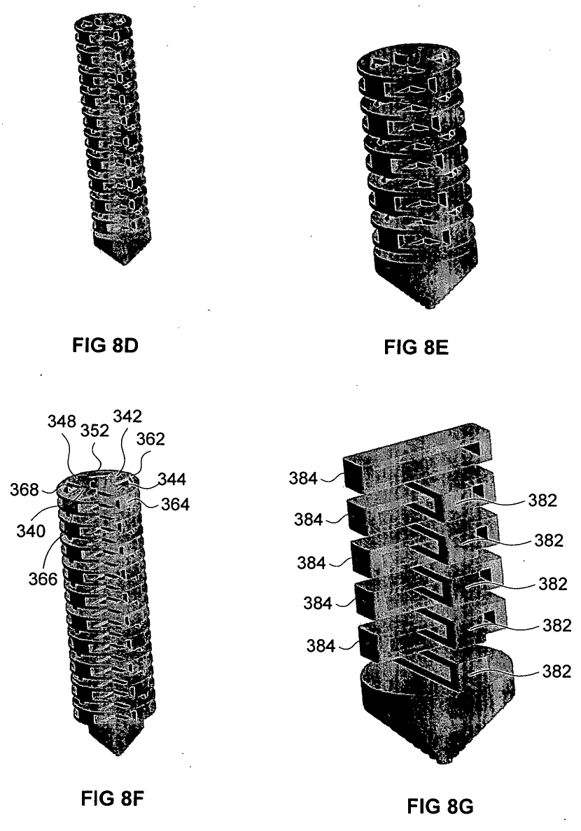

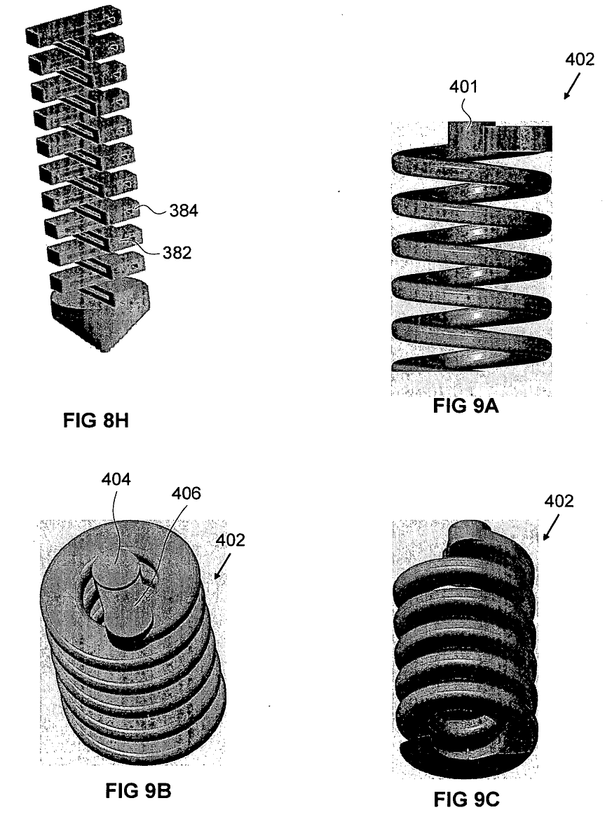

FIG. 8A depicts a perspective view of a different bellows-type of compliant probe 300. In this embodiment a contact element 304 of probe 300 is not located at the end of a cantilever arm as in FIGS. 7A and 7B but instead is located on the center line 306 of the bellows. FIG. 8B depicts a cut view as seen along lines 8B-8B of a portion of the same probe element such that the interior portions of the probe may be seen. As can be seen in the view of the FIG. 8B the probes include lower and upper disk portions 312 and 316 which are connected to one another by ring-like elements 314 to form compliant sections 318 and adjacent compliant sections are fixed to one another by post-like structures 320. In this embodiment the post-like structures do not have a hollow central section that connects volumes within the individual compliant sections 318 segments of the bellows together and the removal of sacrificial material from the interior portion of the bellow elements requires separate opening for each segment. In other embodiments, the post-like structure may be hollow and removal of sacrificial material may occur via such holes and/or via openings existing in other parts of the probe. FIG. 8C depicts a perspective view of an array 330 of the bellows-type probes of FIGS. 8A and 8B which are mounted on a substrate. The contact elements 304 of the probes 300 are located on their central axes 306 and etching holes 332 can be seen in each of the disk-like elements of the probes in FIG. 8C. It will be understood by those of skill in the art that in a particular application, the number and dimensions of the compliant sections, the post-like connector sections, the materials from which each section is formed may be verified in response to empirical testing or modeling analysis to achieve a design that offers appropriate displacement (i.e. overdrive), contact force, and current carrying capability.

FIGS. 8D-8F depict additional examples of bellows-like probe elements where different numbers of collapsible sections, different configurations of collapsible sections, and/or different probe tip configurations are provided. In the embodiments of FIG. 8D-8F, the disk elements of FIGS. 8A-8C have been replaced by bar elements 342, 344, 346, and 348 connected to one another by an outer ring 352, while the ring elements 314 of FIGS. 8A-8C have been replaced by small ring segments 362, 364, 366, and 368 that connect individual upper and lower bars together. The compliant elements of the illustrated probes have large openings and thus the probes do not have a traditional bellows-like appearance but they function in substantially the same manner but offer greater compliance and easier removal of sacrificial material. By adjusting the size of the openings, the numbers of the compliant elements, the size of the central shaft and the outer supports (i.e. ring segments), the compliance and over travel (travel capability after initial contact with a pad or other surface) of the probes may be adjusted to any desired values. In some embodiments, the configurations of different collapsible elements may vary from layer-to-layer (e.g. the diameters may vary, the thickness of the disk-like elements or bars may vary. In still other embodiments other tip configurations may be formed.

FIGS. 8G and 8H depict perspective views of two additional probes that offer compliance in a manner similar to the bellows-like structures discussed above. FIG. 8G provides a compliant probe structure using alternatingly oriented rectangular compliant sections 382 and 384.

As with the embodiments of FIGS. 5 and 6, various alternative embodiments to the probes of FIGS. 7A and 7B, and 8A-8H exist. Some of the alternatives noted for FIGS. 5 and 6 are also applicable alternatives to the embodiments of FIGS. 7A and 7B, and 8A-8H. In some alternatives, the compliance of each individual compliant section need not be the same while in some embodiments it will be substantially the same. In some embodiments, the compliance need not be the same in all radial directions while in others the compliance will be uniform.

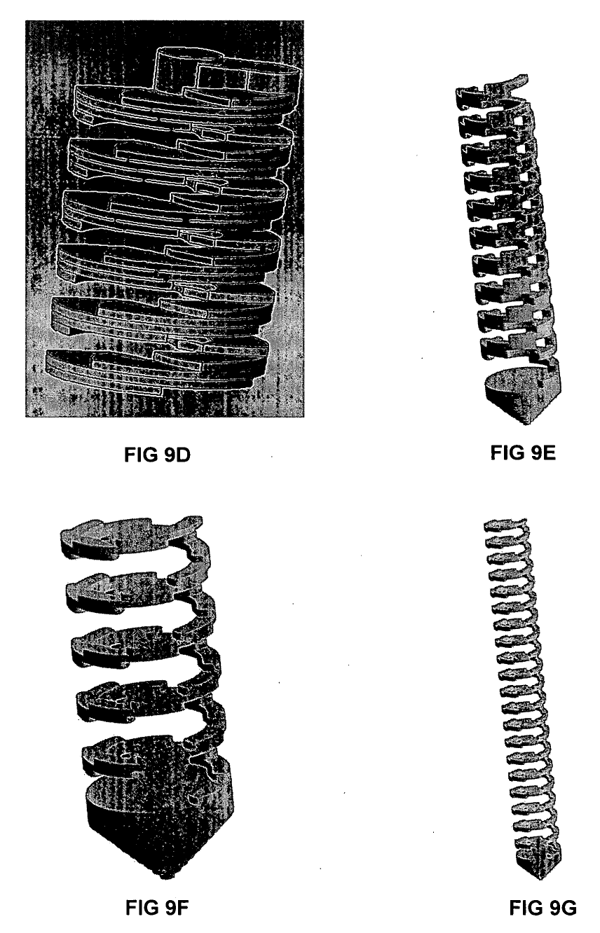

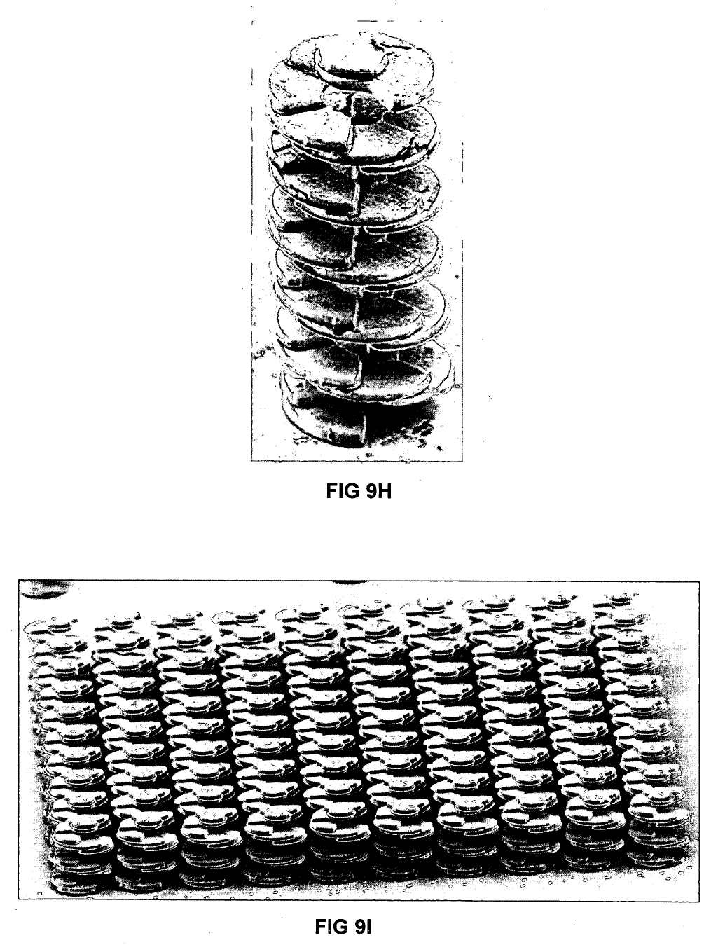

FIGS. 9A-9C depict various views of a CAD design of a helical probe according to an embodiments of the invention. In this embodiment, the probe 402 has a contact element 404 which is positioned toward the central axis of the probe 402 at the end of an extension arm 406. Helical probes of the type shown in these figures provide more uniformity of stress distribution along the probe length than is offered by designs such as that depicted in FIGS. 5A-5D. This more uniform distribution of stress may result in lower amounts of peak stress which in turn can result in long life and less failure frequency. The designs of the probes of FIGS. 5A-5D and 9A-9C differ by more than what initially might be considered to be merely the quantization of the smooth sloping curves of the probes of FIGS. 9A-9C into discrete layer levels. The probes of FIGS. 5A-5D are composed of substantially planar elements that are connected by periodic transitional risers 106 which have horizontal extending dimensions that are common to both the previous and subsequent layers of horizontally extending structures. On the other hand, the quantization of the structures of FIGS. 9A-9C will result in layers of structural material that are progressively offset form one another where each layer will have a portion that overlays a structural material on a previous layer and is overlaid by structural material on a subsequent layer. Such uniform stair stepping is shown in the designs of FIGS. 9D-9G.

FIGS. 9D-9G depict designs of various helical probe structures having different numbers of turns, different pitches, different lengths, and/or different tip configurations wherein the stair stepping of each layer is made a part of the design as opposed to allowing a slicing or layering operation to insert quantized levels, or stair steps, into a sloping helically designed structure. The different probes of FIGS. 9D-9G may offer different amounts of compliance or different extents of compressibility. As with the prior embodiments, various alternative embodiments to the probes of FIGS. 9A-9G are possible. For example, in an array of probe elements like those set forth in FIGS. 9A-9G, the rotational orientation may be the same for all probes or it may be reversed for some probes. In other alternative embodiments the rotational pitch (i.e. the amount of rotation per unit height) may change at various heights within the probe, the thickness of individual structural elements may change, and/or the number of layers of each individual probe segment may increase. As indicated in FIGS. 9E-9F, the contact element or tip structure need not be connected to the spring element of the structure via an extension arm but may be connected in various ways.

FIG. 9H depicts a helical probe, either of the sloped configuration which was quantized as a result of a layering operations or which was designed to have uniform stair steps, and which has been formed in an electrochemical fabrication process.

When building arrays (as shown in FIG. 9I) of probes of the types depicted in FIGS. 9A-9H, or of various other types described herein, the probes can be formed with a spacing that locates them closer than a predefined minimum feature size (for a further discussion of minimum feature size see U.S. patent application Ser. No.______ (Microfabrica Docket No. P-US120-A-MF), which is filed concurrent herewith by Lockard et al, and entitled “Three-Dimensional Structures Having Feature Sizes Smaller Than a Minimum Feature Size and Methods for Fabricating”). In some embodiments, some probes may overlap portions of space associated with one or more adjacent probes since the actual overlapping portions exist on different levels or layers (see FIG. 9I). In still other array designs, it may be possible to cause some adjacent probes to short together upon compression, to enhance current carrying capability, to aid in surface scrubbing by causing some horizontal motion (e.g. relative motion) of probe tips.

It should also be noted that each step of helical probes, such as those described herein, and each step of other compliant probes described herein, offer an amount of compliance the sum of which provides the compliance of the entire probe element. The compliance associated with any given step is based on the physical dimensions of the step (e.g. thickness width, length, etc.), its relationship to lower and upper steps, and the properties of the material or materials from which it is formed. Though a design may be formed to have a certain compliance and though layers thicknesses, for example, are theoretically intended to be specific amounts that will result in an overall compliance, in practice thicknesses of layers may vary slightly which may result in individual layers (e.g. stair steps) not contributing the intended compliance, but it is believed that as a result of forming the structures form a plurality of layers, the overall compliance of the formed structures will be more uniform than that dictated by absolute compliance associated with individual layers. In particular, some layers will be too thickness and will offer less compliance while other layers may be too thin and offer excess compliance, so long as the layer thicknesses do not vary excessively from desired amounts, it is anticipated that over all compliance will average out to a value that is close to a desired value. In fact, during separate formation processes, layer thicknesses may vary differently between different builds but the net thickness of the overall structure will be within a tolerance of a single layer thickness and the variations in compliance associated with individual layers will be averaged out to yield structures from build-to-build that are closer in compliance than might otherwise be anticipated.

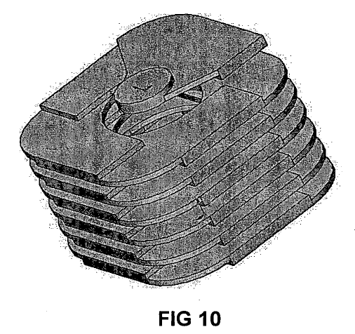

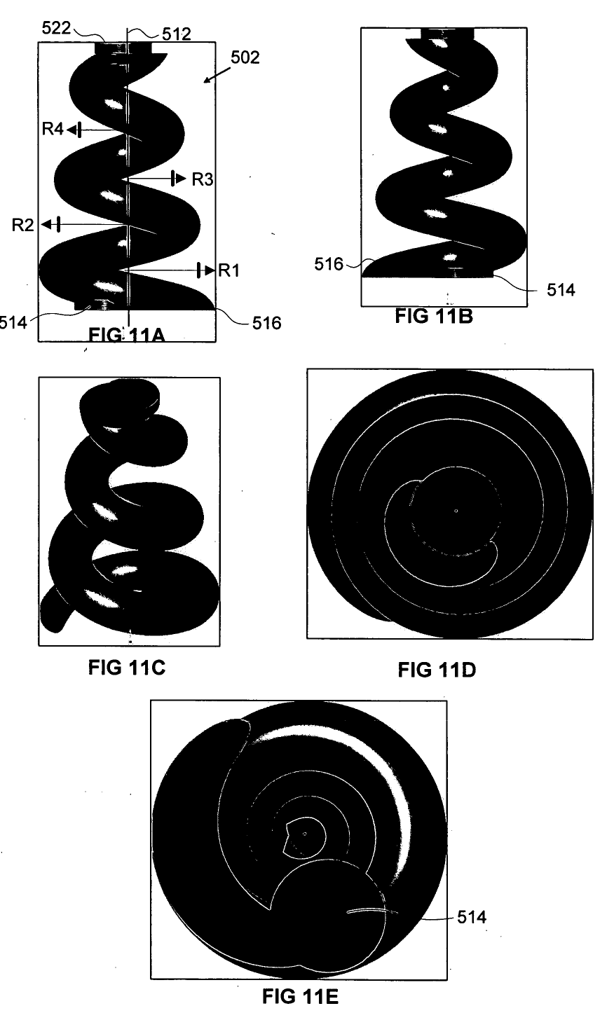

FIG. 10 provides a perspective view of an alternative helical probe design where the spiraling rings take on a more rectangular shape and where the stair steps which would result from a layer-by-layer build up of spiraling structure are shown.

Various other spiral probe embodiments exist. For example, individual spiraling segment may be formed with straight lines or lines with angles as opposed to each segment being formed from curved elements.

FIGS. 11A-11E provide various views of an alternative helical probe 502 configuration where the radius R1-R4 of the spiraling elements (from a center line 512 of the probe) decreases with increasing distance from the substrate and where an enhanced support structure 514 is added to the region of spiraling arm 516 that lifts or separates from a substrate on which the probe was formed or to which the probe is transferred (e.g. via solder bonding, conductive epoxy, or the like). The progressively decreasing radius allows more uniformly distributed stress to be obtained than that offered by the probes of FIGS. 9A-9C since a smaller transitional change exists in moving from the spiraling regions to the contact region 522. As with the prior embodiments various alternatives exist including different numbers of rotation between a substrate and a contact tip, different starting radius, different rate of inward spiraling per rotation, different thicknesses of the spiraling arms, different cross-sectional shapes of the arms (e.g. instead of a circular cross-section as shown, a flat or ribbon like cross-section may be used).

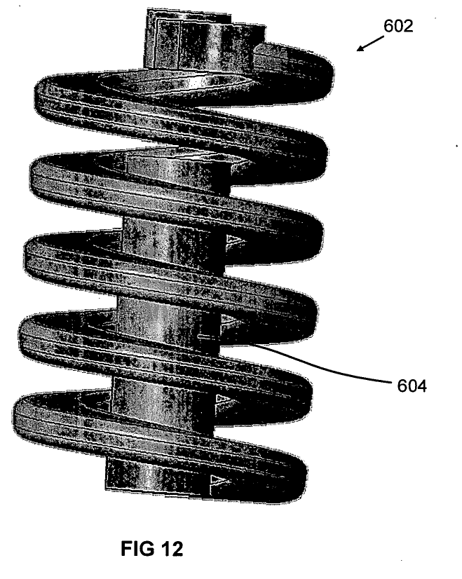

FIG. 12 provides a perspective view of another alternative helical probe configuration 602 that is similar to that depicted in FIGS. 9A-9C with the exception that a fixed rod 604, i.e. a “keeper”, is located in the central opening of the helix which may perform one or both of two functions (1) limit the horizontal, i.e. lateral, displacement that the helical can undergo when it is subjected to a compressive force and (2) provide a hard stop for vertical tip motion if it is long enough and if such a hard stop is desired. The use of a keeper may stop or at least limit unwanted lateral movement without otherwise affecting spring compliance. Other design approach may require a spring redesign which might effect not only lateral displacement but also vertical spring constant and/or deflection. The keeper may also act as a shorting element during compression so as to increase the current carrying capability of the probe and or reduce any inductive properties of the probe associated with its helical configuration. In some alternative embodiments, the keeper may provide some compliance. For example, it may not provide an absolutely hard stop but it none the less provides an effective stop while simultaneously providing a guaranteed electrical connections or short.

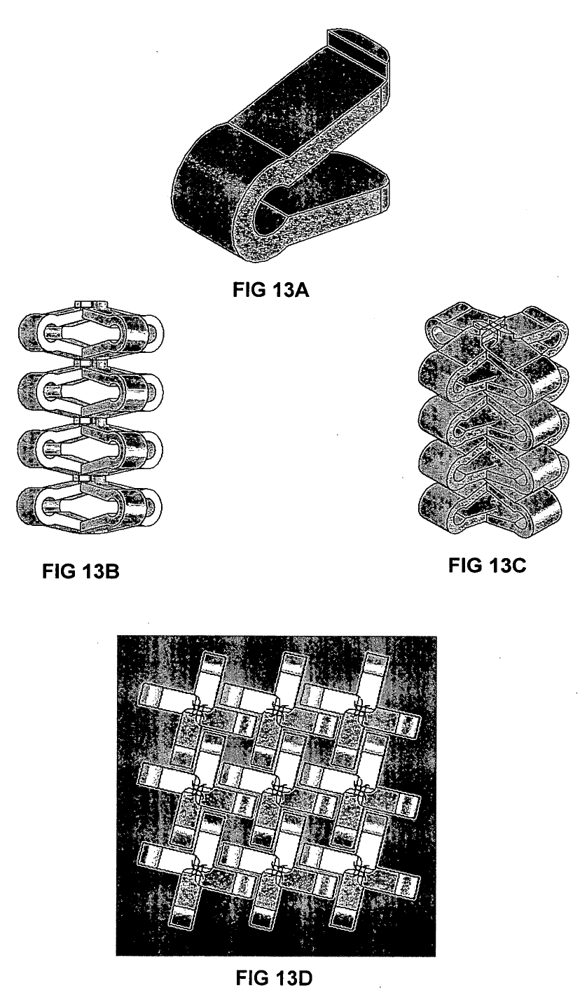

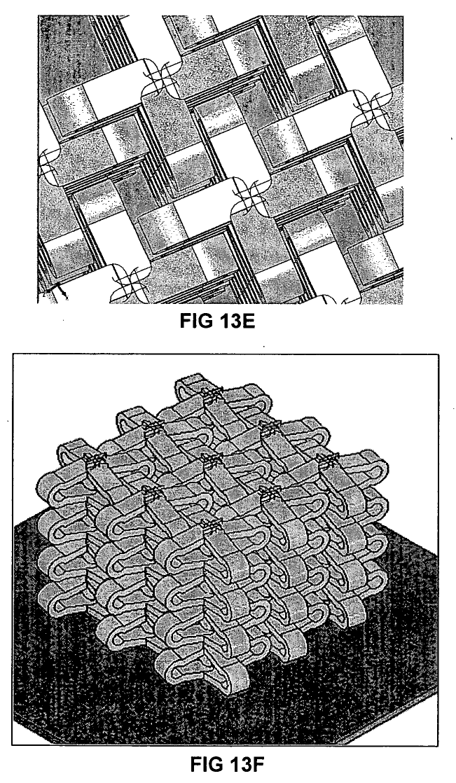

FIG. 13A provides a perspective view of part of a basic compliant structure from which probe elements may be formed. Probe specifications typically call for large deflections but Load-displacement specifications and resistance specifications require a very stiff structure. These requirements typically eliminate the ability to form very long, floppy, winding structures (which would allow for significant displacement) which results in a stiffness which typically results in high stress and strain to achieve a high deflection. The existence of high stress and strain may lead to shortened probe life The compliant structure of FIG. 13 may offer a comprise that can be used to achieve desired deflections without stress and strain getting too high. The overall stiffness is tunable. Deflection in the spans converts to slight angular changes in the notch while the radius of curvature of the notch reduces strain concentrations.

FIGS. 13B and 13C provide two different perspective views of a probe element created from a plurality of the basic structures of FIG. 13A. FIGS. 13D-13F provide various views of an array of the probe structures of FIGS. 13B and 13C where the elements are set into the array at slight angles to one another to allow tighter packing of the individual probes. In some embodiments the upper most portion of the probe structures of FIGS. 13B and 13C may provide a contact structure or alternatively a contact tip may formed on the structure, the structure formed upside down on the tip, or a contact tip bonded to the structure.

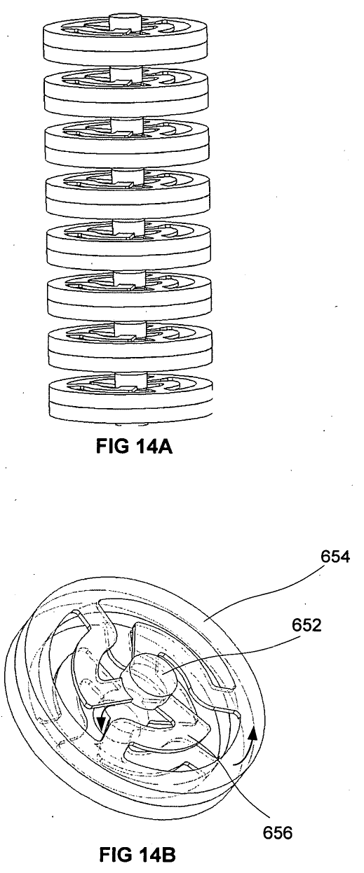

FIG. 14A shows bellows-like probe of another embodiment of the invention which may offer greater compliance than the bellows probe previously described and which may also provide a scrubbing function (i.e. a wiping function of one or more probe tips as the probe is compressed. This extra compliance and possible scrubbing functionality arises from the upper and lower surfaces of each compliant section being formed from and outer ring and oblique arms (three are shown per level, but fewer or more are possible). A number of ‘levels’ are shown, but more or fewer can be used. Indeed, part of the probe may be of a different design than what is shown, and the design shown can be use as a section of the probe to provide a scrubbing rotation. When the structure is compressed and the rings are forced closer together, it is believed that they may be forced to rotate. Tips provided on the outpost compliant section provide contact with and scrubbing of a contact pad, penetrating the oxide layer, to make good electrical contact on the device which is being tested.

FIG. 14B shows two back-to-back units of a probe with spoked wheels (together forming a compliant section of the probe of FIG. 14A). The two units each consist of a central shaft 652, a rim 654, and three arms 656 (different numbers are possible) which extend from the rim inwards, twisting counterclockwise before connecting to the shaft (a design having the mirror image of this is also possible). If the two back-to-back units were to be placed side-by-side instead, it could be easily seen that they are the same: the arms in both cases twist counterclockwise from rim to shaft (if in fact the two units were mirror images of one another, the resulting 2-unit assembly, and everything based on it, would not rotate when its length is changed). When the topmost shaft is pressed toward the center of the two-unit assembly, it not only makes the assembly shorter, but also pulls on the rim tangentially so as to give it a slight counterclockwise twist (as seen from the top, as shown). While this is occurring, the bottommost shaft is also being pressed toward the center of the assembly by the force applied to it through the bottommost rim and arms; this motion imparts an additional counterclockwise (as seem from the top) twist to the bottommost shaft, which is added to the counterclockwise twist produced by the topmost unit. The result of compressing both units is thus a reduction in length plus a doubled counterclockwise twist of the lowermost shaft with respect to the uppermost shaft.

If a number of double units (compliant sections) are stacked (e.g., eight as shown in FIG. 14A) each applies a torque to the unit below it, with the result that as more units are added, not only is the entire structure compressed axially when pressure is applied, but the small twists are added together, producing a significant twist of the shaft on the lowermost unit. In order to achieve scrubbing, this lowermost shaft can be attached to one or more tips. If in some embodiments, additional axial compliance is need without additional twist, then mirror-image pairs of units can be introduced, which will compress without twisting. To remove twist produced by units producing a counterclockwise twist as shown, one can also introduce units producing a clockwise twist. It should also be noted that while the arms shown in FIG. 14B only wrap less than 120° in their passage from rim to shaft, much longer arms, wrapping in some cases up to or in excess of 360° (nested to avoid collision with one another) can be designed, which can provide more compliance and potentially greater twist.

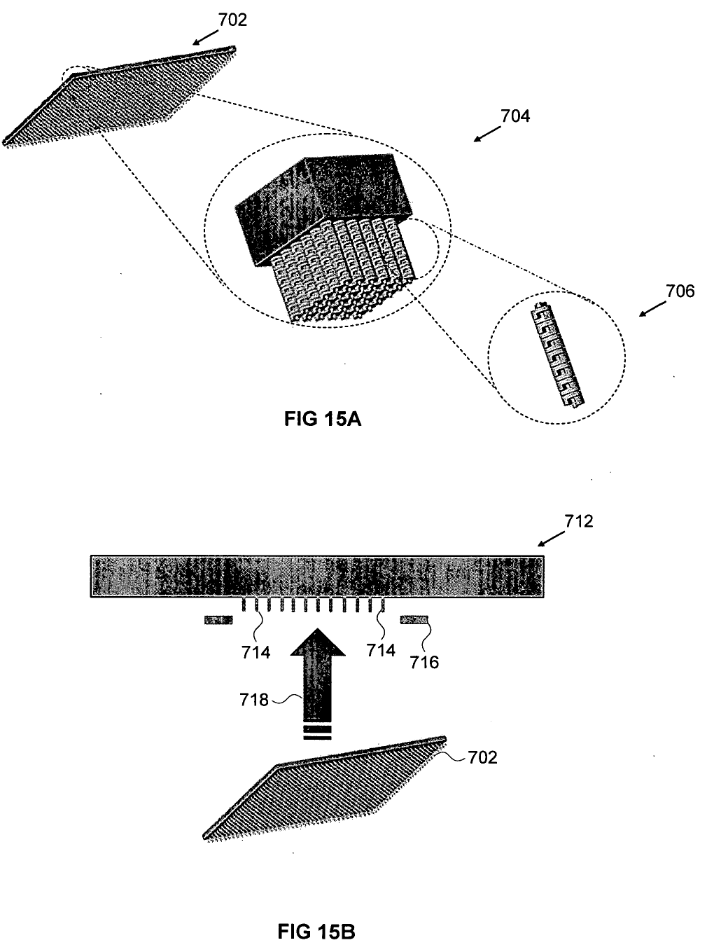

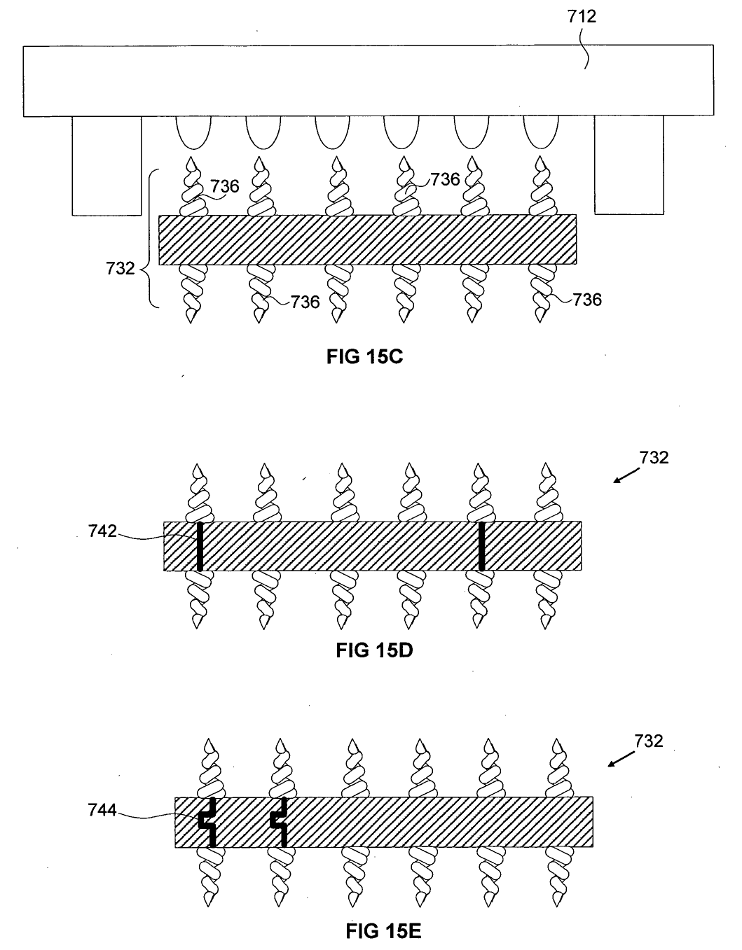

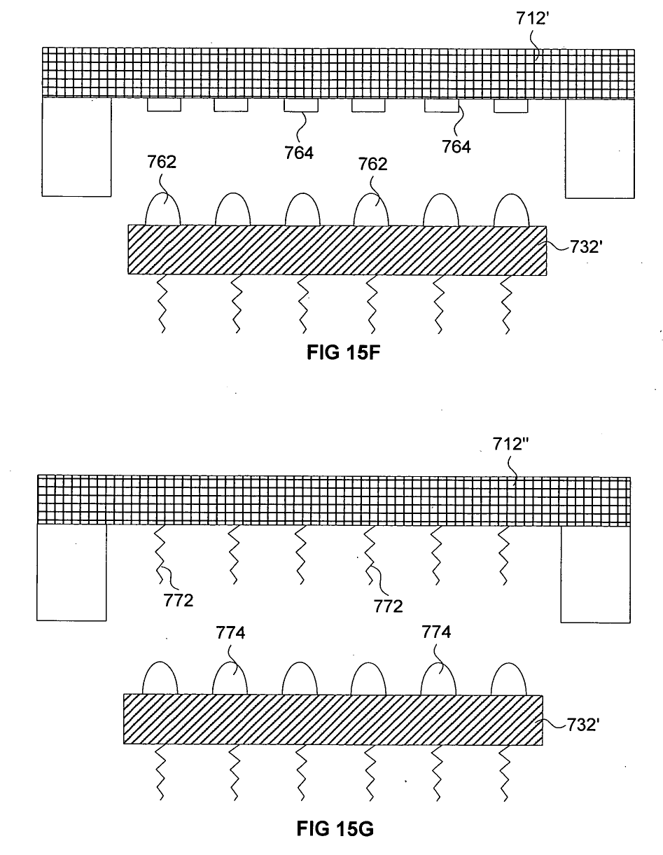

FIGS. 15A and 15B depict a probe array chip (probe chip) according to another embodiment of the invention. FIG. 15A depicts a large probe chip 702 which includes a large array. The figure also shows an enlarged view of a portion 704 of the array and an even larger view of a single element or probe 706 of the probe array. FIG. 15B depicts a space transformer 712 or the like having contact elements 714 (e.g. bumps, spring probes, or the like) extending therefrom along with a retention socket for holding a probe chip against the space transformer. As indicated, a probe chip 702 is being directed into the socket in the direction of arrow 718. FIGS. 15C-15G depict enlarged views and alternative views to how a probe chip may be temporarily be mounted or contacted to a space transformer. As indicated in FIG. 15C the probe array 732 may include probe elements 736 extending form both the front and back sides where the probe elements on the space transformer 712 side need not necessarily meet the same stringent requirements as do the device touching probe elements since the contact between the probe array and the space transform may only occur a very limited number of times during the course of the life of the probe array. FIGS. 15D and 15E indicate two alternative configurations showing how the probe elements on either side of the chip may couple (straight through via 742 or via with a non-straight or complex configuration 744) to their counterparts on the other side of the chip. In still other alternative configurations, the connection from one side of the support portion of the probe array to the other side of the probe array may include interactions with various added electrical components and the like. FIGS. 15F and 15G show other alternative configurations where the space transformer 712′ and 712″, respectively, and the probe array chips 732′ and 732″, respectively make electrical contact. In FIG. 15F the space probe chip includes solder bumps 762 that can be bonded to pads 764 on the space transformer 732′ while in 15G the space transformer 712″ it includes compliant structures (e.g. springs) 772 while the probe chip 732′ include solder bumps 774.

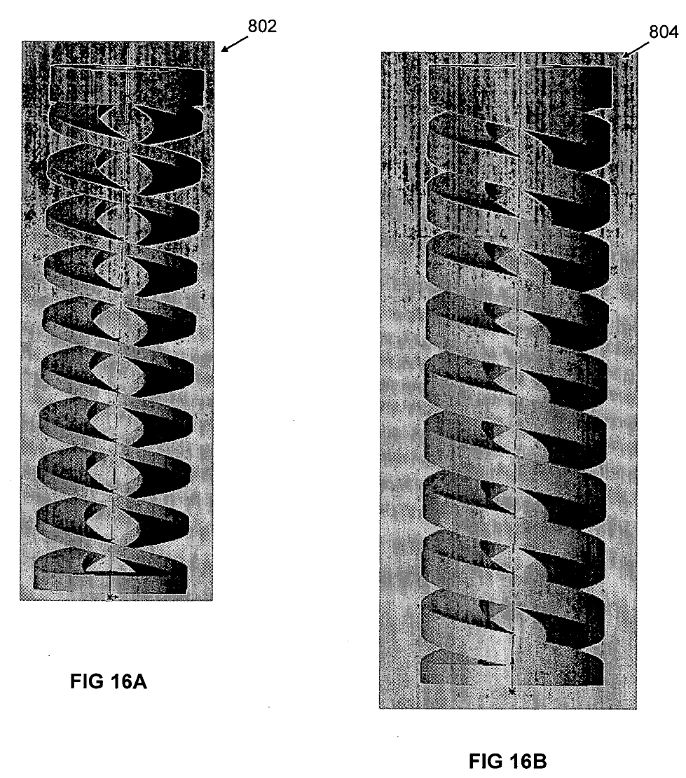

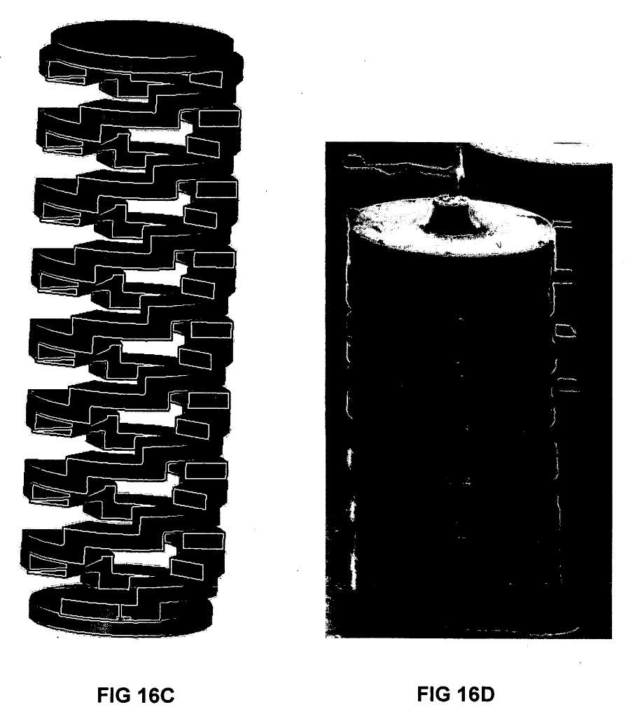

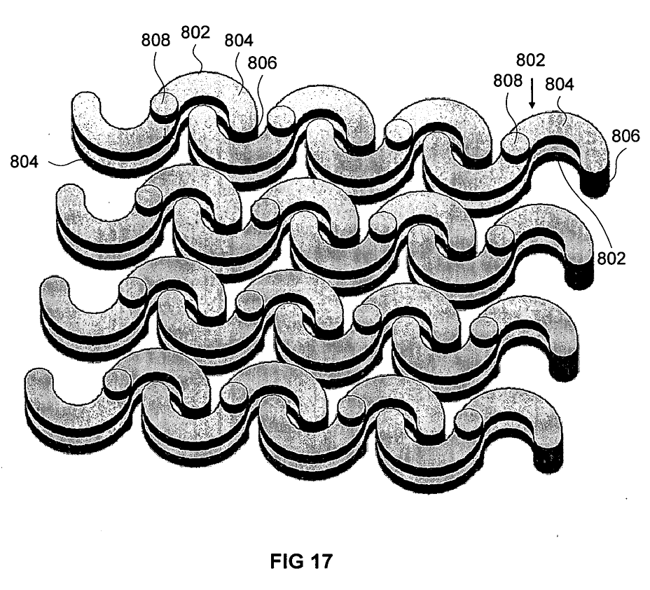

FIGS. 16A-16C provide perspective views of double helix probes 802 and 804, respectively. As shown, no contact tips are included but in alternative embodiments, any of a variety of tips may be formed as part of probes, the probes may be formed on them, or they may be transferred to the probes or the probes to them. In alternative embodiments, different thicknesses and widths of the spiral elements may be used, different pitches may be used, different overall probe heights, different number of turns, different diameters, and even different types of probe bodies may be attached to these double helix probes. In still other embodiments, higher order helices (e.g. triple or quadruple) may be used and or the spirals of the helix may take on different configurations (e.g. square, rectangular, and the like).

FIG. 16C. provides a perspective view of a design of a double helix probe which depicts layer-to-layer discontinuities (i.e. stair steps) that may result from a layer-by-layer build up of the structure or may be formed as an intentional part of the design where each stair step level may represent a single layer of multiple layers.

FIG. 16D. provide a perspective view of an SEM image of a double helix probe structure similar to that of FIG. 16D but with fewer complete turns and with a contact tip formed at its upper end.

FIG. 17 depicts an array of tessara-like probes 802 each possessing a compliant section formed from double S-shaped elements 804 separated from one another by end supports 806 and with post-like structures 808 on the upper surface of the top element and on the lower surface of the bottom element (not visible). The upper post-like structure 808 may act as a contact tip, a support structure for a contact tip, or as a connection element for other compliant structure and where the lower post-like structure may act as a connection element for connecting the probe to a base (e.g. contact pad on an electronic device such a space transformer) or as a connection element for another compliant probe structure that may be added to enhance the compliance or over travel capability of a compound probe structure. Each probe includes a base contact element that contacts a support (not shown, e.g. a space transform, circuit board or the like). The contact element supports the central portion of an elongated and curved flexible member 802. These elements provide compliance by allowing the two flexible members to approach one another along the central axis of each probe. In alternative embodiments, the probes may have different curvatures where the curvatures are configured so as to allow interlacing of the probes whereby the compliance offered is greater than that offered by two straight flexible elements with a similar packing density for the array. In still other embodiments, such probes may be extended to include additional pairs of flexible members.

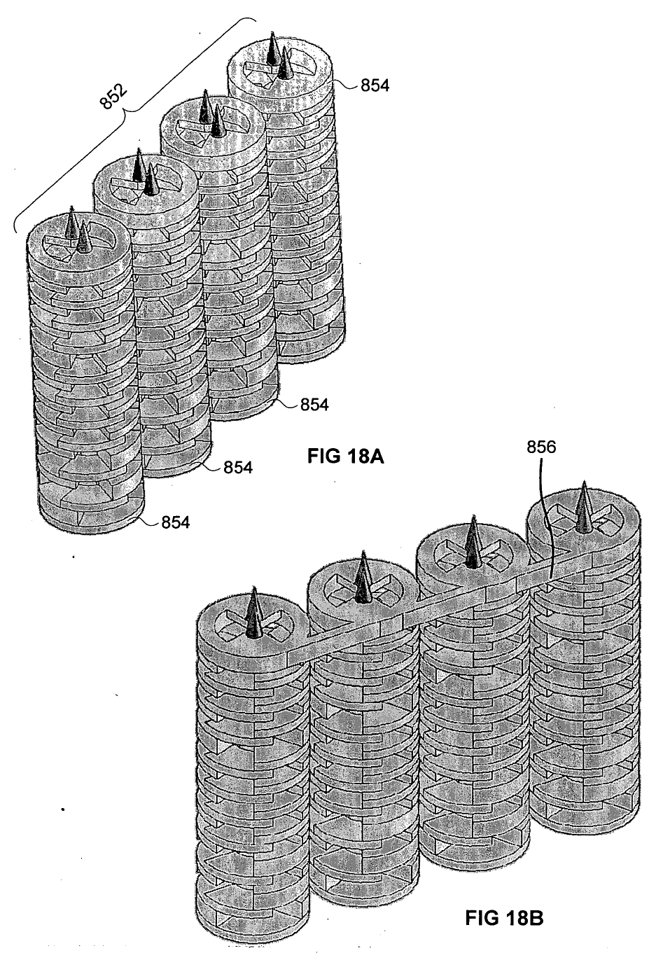

FIG. 18A depicts an array 852 of four probe elements 854 where it is assumed that the probes are to contact a single pad or multiple pads that carry a common signal or voltage. In such cases, bad contact between one or more probes and the pad or groups of pads can cause the other probes to receive excess current and thus damage those probes. Such bad contact may result from contamination or ineffective scrubbing. FIG. 18B depicts an example of a probe array where probes that carry common signals are connected to one another by a bridging element 856 that allows each probe to carry a portion of the current even if some probes do not make good contact with a pad. As shown, the bridging element is a straight bar that connects the probes to one-another in proximity to the probe tips. In other embodiments, other bridging element configurations are possible. These other configurations may include bridges that offer more compliance to allow somewhat more autonomous vertical displacement of the probe elements.

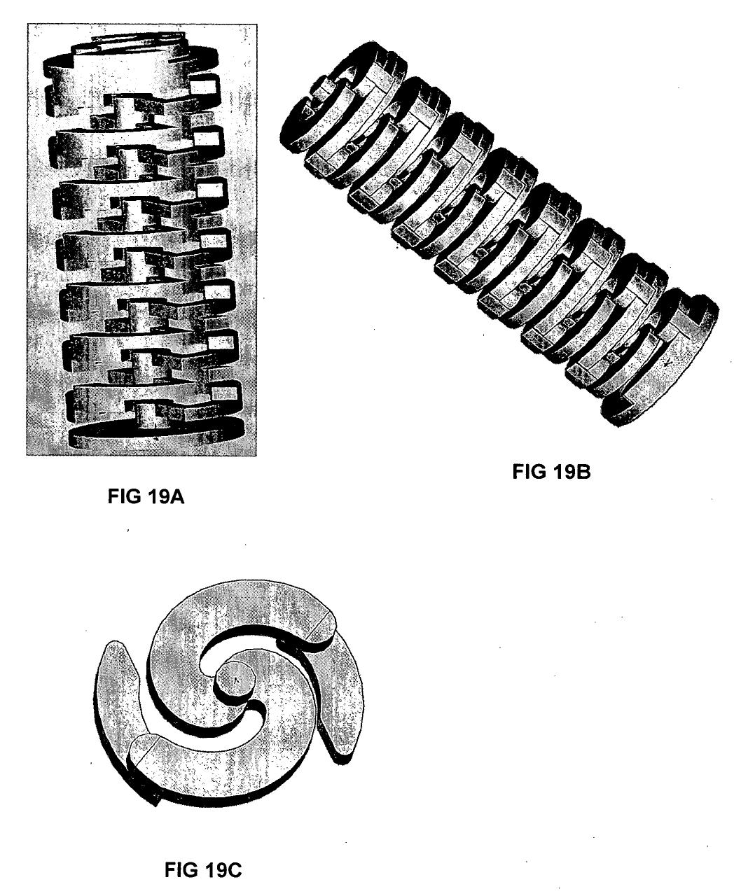

FIG. 19A depicts a perspective view of another embodiment of the invention which provides double helical probe structures with spiral elements (elements that extend ½ a full turn) form separate spiral sections that attach to spaced but centrally located independent elements.

FIG. 19B depicts a perspective view of another embodiment of the invention which provides double helical probe structures with spiral elements (elements that extend 1 full turn) form separate spiral sections that attach to spaced but centrally located elements.

FIG. 19C depicts a perspective view of two layer levels of a probe of FIG. 19B.

As with the other embodiments set forth herein, various alternatives to the embodiments of FIGS. 19A-19C are possible. For example such alternative may have different number of compliant sections, they may have one or more specially figured contact tips added, each compliant section may extend a rotational amount which is different from the a half rotation (as shown in FIG. 19A) or a full rotation (as shown in FIG. 19B, and the like.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,384 which was filed May 7, 2004 by Zhang, et al. which is entitled “Method of Electrochemically Fabricating Multilayer Structures Having Improved Interlayer Adhesion” and which is hereby incorporated herein by reference as if set forth in full.

Further teachings about planarizing layers and setting layers thicknesses and the like are set forth in the following US Patent Applications which were filed Dec. 31, 2003: (1) U.S. Patent Application No. 60/534,159 by Cohen et al. and which is entitled “Electrochemical Fabrication Methods for Producing Multilayer Structures Including the use of Diamond Machining in the Planarization of Deposits of Material” and (2) U.S. Patent Application No. 60/534,183 by Cohen et al. and which is entitled “Method and Apparatus for Maintaining Parallelism of Layers and/or Achieving Desired Thicknesses of Layers During the Electrochemical Fabrication of Structures”. These patent filings are each hereby incorporated herein by reference as if set forth in full herein.

Further teaching about microprobes and electrochemical fabrication techniques are set forth in a number of US Patent Applications which were filed Dec. 31, 2003. These Filings include: (1) U.S. Patent Application No. 60/533,975 by Kim et al. and which is entitled “Microprobe Tips and Methods for Making”; (2) U.S. Patent Application No. 60/533,947 by Kumar et al. and which is entitled “Probe Arrays and Method for Making”; (3) U.S. Patent Application No. 60/533,948 by Cohen et al. and which is entitled “Electrochemical Fabrication Method for Co-Fabricating Probes and Space Transformers”; and (4) U.S. Patent Application No. 60/533,897 by Cohen et al. and which is entitled “Electrochemical Fabrication Process for Forming Multilayer Multimaterial Microprobe structures”. Additional pending patent applications include: (1) U.S. Patent Application No. 60/540,511 filed by Kruglick et al. on Jan. 29, 2004, which was entitled “Electrochemically Fabricated Microprobes” and (2) U.S. patent application Ser. No. 10/772,943 filed by Kruglick et al. on Feb. 4, 2004, which was entitled “Electrochemically Fabricated Microprobes”. These patent filings are each hereby incorporated herein by reference as if set forth in full herein.

Teachings concerning the formation of structures on dielectric substrates and/or the formation of structures that incorporate dielectric materials into the formation process and possibility into the final structures as formed are set forth in a number of patent applications filed on Dec. 31, 2003. The first of these filings is U.S. Patent Application No. 60/534,184, which is entitled “Electrochemical Fabrication Methods Incorporating Dielectric Materials and/or Using Dielectric Substrates”. The second of these filings is U.S. Patent Application No. 60/533,932, which is entitled “Electrochemical Fabrication Methods Using Dielectric Substrates”. The third of these filings is U.S. Patent Application No. 60/534,157, which is entitled “Electrochemical Fabrication Methods Incorporating Dielectric Materials”. The fourth of these filings is U.S. Patent Application No. 60/533,891, which is entitled “Methods for Electrochemically Fabricating Structures Incorporating Dielectric Sheets and/or Seed layers That Are Partially Removed Via Planarization”. A fifth such filing is U.S. Patent Application No. 60/533,895, which is entitled “Electrochemical Fabrication Method for Producing Multi-layer Three-Dimensional Structures on a Porous Dielectric”. These patent filings are each hereby incorporated herein by reference as if set forth in full herein.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, and the like.

| US Pat App No, Filing Date | |
|---|---|
| US App Pub No, Pub Date | Inventor, Title |
| 10/677,556 - | Cohen, “Monolithic Structures |
| Oct. 1, 2003 | Including Alignment and/or Retention |
| | Fixtures for Accepting Components” |
| 10/830,262 - | Cohen, “Methods of Reducing |
| Apr. 21, 2004 | Interlayer Discontinuities in |
| | Electrochemically Fabricated Three- |
| | Dimensional Structures” |
| 10/271,574 - | Cohen, “Methods of and Apparatus |
| Oct. 15, 2002 | for Making High Aspect Ratio Micro- |
| 2003-0127336A - | electromechanical Structures” |
| Jul. 10, 2003 | |
| 10/697,597 - | Lockard, “EFAB Methods and |
| Dec. 20, 2002 | Apparatus Including Spray Metal or |
| | Powder Coating Processes” |
| 10/677,498 - | Cohen, “Multi-cell Masks and |
| Oct. 1, 2003 | Methods and Apparatus for Using |
| | Such Masks To Form Three-Dimensional |
| | Structures” |
| 10/724,513 - | Cohen, “Non-Conformable Masks and |
| Nov. 26, 2003 | Methods and Apparatus for Forming |
| | Three-Dimensional Structures” |
| 10/607,931 - | Brown, “Miniature RF and Microwave |
| Jun. 27, 2003 | Components and Methods for |
| | Fabricating Such Components” |
| 10/841,100 - | Cohen, “Electrochemical |
| May 7, 2004 | Fabrication Methods Including Use |
| | of Surface Treatments to Reduce |
| | Overplating and/or Planarization |
| | During Formation of Multi-layer |
| | Three-Dimensional Structures” |
| 10/387,958 - | Cohen, “Electrochemical |
| Mar. 13, 2003 | Fabrication Method and Application |
| 2003-022168A - | for Producing Three-Dimensional |
| Dec. 4, 2003 | Structures Having Improved Surface |
| | Finish“ |
| 10/434,494 - | Zhang, “Methods and Apparatus |
| May 7, 2003 | for Monitoring Deposition Quality |
| 2004-0000489A - | During Conformable Contact Mask |
| Jan. 1, 2004 | Plating Operations” |
| 10/434,289 - | Zhang, “Conformable Contact |
| May 7, 2003 | Masking Methods and Apparatus |
| 20040065555A - | Utilizing In Situ Cathodic Activation |
| Apr. 8, 2004 | of a Substrate” |
| 10/434,294 - | Zhang, “Electrochemical |
| May 7, 2003 | Fabrication Methods With Enhanced |
| 2004-0065550A - | Post Deposition Processing Enhanced |
| Apr. 8, 2004 | Post Deposition Processing” |
| 10/434,295 - | Cohen, “Method of and Apparatus |
| May 7, 2003 | for Forming Three-Dimensional |
| 2004-0004001A - | Structures Integral With Semiconductor |
| Jan. 8, 2004 | Based Circuitry” |
| 10/434,315 - | Bang, “Methods of and Apparatus |
| May 7, 2003 | for Molding Structures Using |
| 2003-0234179A - | Sacrificial Metal Patterns” |
| Dec. 25, 2003 | |
| 10/434,103 - | Cohen, “Electrochemically |
| May 7, 2004 | Fabricated Hermetically Sealed |
| 2004-0020782A - | Microstructures and Methods of and |
| Feb. 5, 2004 | Apparatus for Producing Such |
| | Structures” |
| 10/841,006 - | Thompson, “Electrochemically |
| May 7, 2004 | Fabricated Structures Having |
| | Dielectric or Active Bases and |
| | Methods of and Apparatus for |
| | Producing Such Structures” |
| 10/434,519 - | Smalley, “Methods of and |
| May 7, 2003 | Apparatus for Electrochemically |
| 2004-0007470A - | Fabricating Structures Via Interlaced |
| Jan. 15, 2004 | Layers or Via Selective Etching |
| | and Filling of Voids” |
| 10/724,515 - | Cohen, “Method for Electro- |
| Nov. 26, 2003 | chemically Forming Structures |
| | Including Non-Parallel Mating of |
| | Contact Masks and Substrates” |
| 10/841,347 - | Cohen, “Multi-step Release |
| May 7, 2004 | Method for Electrochemically |
| | Fabricated Structures” |
| 60/533,947 - | Kumar, “Probe Arrays and Method |
| Dec. 31, 2003 | for Making” |

Various other embodiments of the present invention exist. Some of these embodiments may be based on a combination of the teachings herein with various teachings incorporated herein by reference. Some embodiments may combine the various features of the different embodiments set forth above to obtain additional embodiments. Some embodiments may not use any blanket deposition process and/or they may not use a planarization process. Some embodiments may involve the selective deposition of a plurality of different materials on a single layer or on different layers. Some embodiments may use blanket depositions processes that are not electrodeposition processes. Some embodiments may use selective deposition processes on some layers that are not conformable contact masking processes and are not even electrodeposition processes. Some embodiments may use nickel as a structural material while other embodiments may use different materials such as gold, silver, or any other electrodepositable materials that can be separated from the copper and/or some other sacrificial material. Some embodiments may use copper as the structural material with or without a sacrificial material. Some embodiments may remove a sacrificial material while other embodiments may not. In some embodiments the anode may be different from the conformable contact mask support and the support may be a porous structure or other perforated structure. Some embodiments may use multiple conformable contact masks with different patterns so as to deposit different selective patterns of material on different layers and/or on different portions of a single layer. In some embodiments, the depth of deposition will be enhanced by pulling the conformable contact mask away from the substrate as deposition is occurring in a manner that allows the seal between the conformable portion of the CC mask and the substrate to shift from the face of the conformal material to the inside edges of the conformable material.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

We claim:

1. A probe device for testing semiconductor die, comprising:
a substrate;
a multi-turn compliant helical conductive element having a proximal end attached directly or indirectly to the substrate, and having a distal end that may be used to contact a pad to be tested.

2. A probe device for testing semiconductor die, comprising:
a substrate;
a multi-turn compliant, conical helical conductive element adhered directly or indirectly to the substrate and extending substantially perpendicular to the substrate along a winding path of progressively narrowing radius, where a distal end of the probe is substantially located at a point along an axis of helix and may be used to contact a pad to be tested.

3. A probe device for testing semiconductor die, comprising:
a substrate; and
a multi-turn helical conductive element adhered directly or indirectly to the substrate and extending substantially perpendicular to the substrate along a spiraling path where a plurality of successive layers define the spiraling path such that it includes a pattern of deposited structural material along a given layer that only partially overlays a pattern of deposited structural material on an immediately preceding layer.

4. A plurality of probes for testing semiconductor die at least some of which were formed in separate formation processes, comprising:
a plurality of probes formed from a plurality of adhered layers of at least one desired material, each probe having a compliance;
at least one substrate for holding a plurality of probes;
wherein the maximum compliance difference between a plurality of probes is less than a summation, for each layer of the plurality of probes, of an absolute value of a maximum difference between compliance associated with portions of the probes on each consecutive pair of layers.

5. A plurality of separate probes for testing semiconductor die, comprising:
a substrate;
a plurality of multi-turn helical conductive elements, each having a proximal end attached directly or indirectly to the substrate, and having a distal end that may be used to contact a pad to be tested, and each formed from a plurality of adhered layers;
wherein the spacing between portions of each probe formed on each layer is greater than a spacing between each probe element.

6. A plurality of separate probes for testing semiconductor die, comprising:
a substrate;
a plurality of multi-turn helical conductive elements, each having a proximal end attached directly or indirectly to the substrate, and having a distal end that may be used to contact a pad to be tested, and each formed from a plurality of adhered layers;
wherein the probes overlap in space but do not contact one another during anticipated levels of compression during use.

7. A probe device for testing semiconductor die, comprising:
a substrate;
a bellow-like, compliant, conductive element having a proximal end attached directly or indirectly to the substrate, and having a distal end that may be used to contact a pad to be tested.
